(19) United States
(12) Patent Application Publication
(10) Pub. No.: US 2002/0048670 A1
(43) Pub. Date: Apr. 25, 2002

(54) Single crystalline silicon wafer, ingot and producing method thereof

(76) Inventors: Hong-Woo Lee, Gumi-shi (KR); Joon-Young Choi, Chilgok-gun (KR); Hyon-Jong Cho, Bucheon-shi (KR); Hak-Do Yoo, Seoul (KR)

Correspondence Address: JACOBSON HOLMAN PLLC, 400 SEVENTH STREET N.W., SUITE 600, WASHINGTON, DC, 20004, US

(21) Appl. No.: 09/742,128

(22) Filed: Dec. 22, 2000

(30) Foreign Application Priority Data
Sep. 7, 2000 (KR) 2000-53188

(51) Int. Cl. B32B 7/02; C30B 15/20

(52) U.S. Cl. 428/218; 117/20

(57) ABSTRACT

The present invention relates to a single crystalline silicon ingot by Czochralski method and, more particularly, to a single crystalline silicon ingot, a wafer and a method of producing a single crystalline silicon ingot in which an oxidation-induced stacking fault ring is distributed widely and which has an agglomerated vacancy point defect area of low density wherein DSOD exists only, without FPD. Accordingly, an oxidation-induced stacking fault area having a micro-vacancy defect area of low density is distributed widely from the ingot edge to the ingot center in a single crystalline silicon ingot and a wafer fabricated by the present invention. As the micro-vacancy defect area has no FPD but may have DSOD, a coarsely agglomerated vacancy point defect area in which FPD and DSOD cohabit is shrunken or even eliminated. Therefore, the present invention improves the product quality as well as device yield.

### BACKGROUND OF THE INVENTION

1. Field of Invention

The present invention relates to a single crystalline silicon ingot by a Czochralski method and, more particularly, to a single crystalline silicon ingot, a wafer and a method of producing a single crystalline silicon ingot in which an oxidation-induced stacking fault ring is distributed widely and which has a agglomerated vacancy point defect area of low density wherein Direct Surface Oxide Defects (“DSOD”) may exist, but without Flow Pattern Defects (“FPD”).

2. Discussion of Related Art

A well-known method for producing a single crystalline ingot for a wafer used for electronic devices such as semiconductor devices is that of Czochralski (hereinafter abbreviated “Cz”). The Cz method makes crystals grow by dipping a single crystalline seed crystal into molten silicon and then pulling it slowly; this process is explained in detail in “Silicon Processing for the VLSI Era,” Volume 1, Lattice Press (1986), Sunset Beach, Calif., by S. Wolf and R. N. Tauber. A general method of producing a single crystalline silicon ingot by the Cz method will be explained in the following description in accordance with the appended drawings.

First of all, a necking step of growing a thin and long crystal out of a seed crystal is carried out, followed by a shouldering step which is performed for growing the crystal radially to attain a target diameter. Then, a body growing step is accomplished to obtain a crystal having a predetermined diameter. A part grown by the body growing step becomes a wafer. After the body growing step has achieved the predetermined length, the body-growing step is terminated, followed by a tailing step of separating the body from the molten silicon by which diameter is reduced All these steps are carried out in a space referred to as a “hot zone” where the molten silicon grows to turn into a single crystalline ingot. The grower includes a quartz crucible, a crucible support, a heater and a heat shield.

As the defect characteristic inside an ingot depends on the sensitivity of the growing and cooling conditions of the crystal, efforts have been made to control the species and distributions of crystal growing defects by controlling the thermal environment near a crystal growing interface. The crystal growing defects are largely divided into an agglomerated vacancy type defect and an agglomerated interstitial type defect. If the amount of vacancy type defects or interstitial type defects exist more than equilibrium concentration, agglomeration is commenced and then systematic defects in the crystal may be evolved. The Voronkov theory, introduced in “The Mechanism of Swirl Defects Formation in Silicon,” Journal of Crystal Growth,” 59, 625 (1982), by V.V. Voronkov, teaches that such defect formation is closely related to a value of V/G wherein V is a pulling rate of an ingot and G is a temperature gradient near a crystal growing interface. Based on the Voronkov theory, an agglomerated vacancy type defect occurs when the value of V/G exceeds a critical value, while an agglomerated interstitial type defect occurs when the value of VIG is lower than the critical value. Therefore, the pulling rate has an influence on the species, sizes and density of the defects existing in the crystal when a crystal is grown according to the given growing environment.

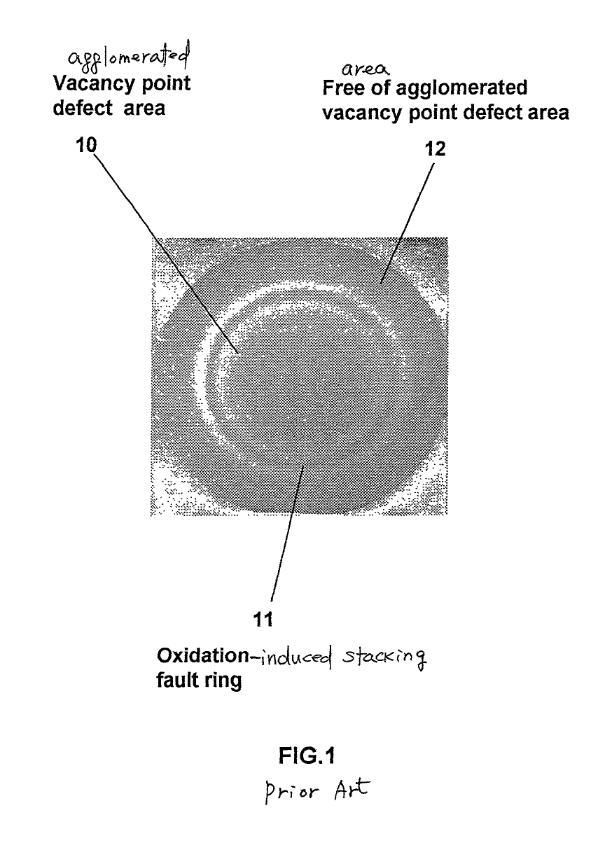

FIG. 1 is a picture of X-ray Topography (“XRT”) showing a horizontal cross-sectional view of a single crystalline silicon ingot according to a related art. Referring to FIG. 1, an oxidation-induced stacking fault ring 11 lies between an agglomerated vacancy point defect area 10 and an area free of agglomerated vacancy point defect 12.

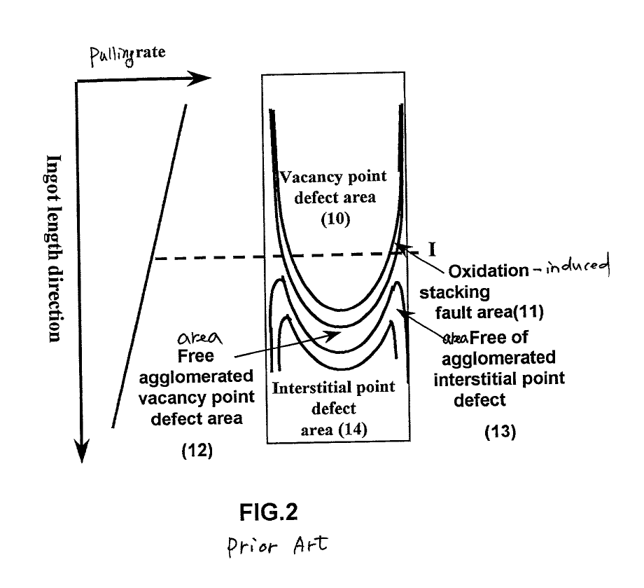

FIG. 2 shows a vertical cross-sectional view of an ingot grown by varying a pulling rate, illustrating the formation of the respective defect areas. Referring to FIG. 2, as the pulling rate slows, an interstitial point defect area 14 is generated. As the pulling rate increases, a vacancy point defect area 10 is generated. An oxidation-induced stacking fault area 11 is generated at a pulling rate between these two pulling rates.

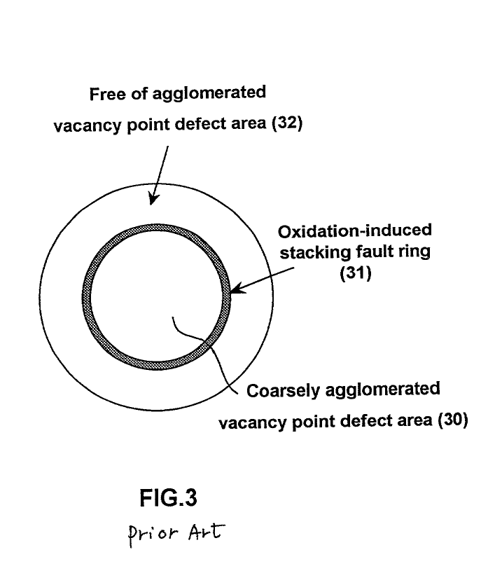

FIG. 3 shows a horizontal cross-sectional view of an ingot corresponding to a region indicated as I in FIG. 2. Referring to FIG. 3, when an ingot is grown by the pulling rate corresponding to I in FIG. 2, a vacancy defect area 30 is widely distributed at the center of the ingot and an oxidation-induced stacking fault ring 31 surrounds the vacancy defect area 30 in a narrow layer. The vacancy defect area 30 includes a high density of vacancy defects such as a Crystal Originated Particle (“COP”) and a Flow Pattern Defect (“FPD”), as well as other defects larger than COP or FPD, therefore being called a coarsely agglomerated vacancy point defect area.

An ingot where the coarsely agglomerated vacancy point defect area is distributed widely therein is not suitable for a wafer on which micro-electronic circuits will be fabricated. In order to solve the problem, the pulling rate may be lowered to reduce the coarsely agglomerated vacancy point defect area. However, as the pulling rate slows, the productivity of ingot production is reduced. In addition, an agglomerated interstitial point defect such as Large Dislocation Pit (“LDP”) defect, much larger than the vacancy type large tissue defect, may occur.

Referring to FIG. 2 and FIG. 3, when the pulling rate is increased, the oxidation-induced stacking fault area 13 is pushed back to the edge of the cross-section of the ingot to leave the agglomerated vacancy point defect distributed throughout the entire cross-section. On the other hand, as the pulling rate is being reduced, the oxidation-induced stacking fault area 13 shrinks to the center of the cross-section. Thus, the oxidation-induced stacking fault area is eliminated eventually, thereby resulting in an area free of agglomerated vacancy point defect 12. Further, when the pulling rate is further reduced, an area free of agglomerated interstitial point defect 13 appears. As the pulling rate is further reduced, an area free of agglomerated interstitial point defect area 14 exists throughout the entire cross-section.

As set forth above, another factor for the defect formation in the single crystal ingot is a temperature gradient near a crystal growing interface. In the conventional method, the cooling speed at the growing interface near the center of the ingot is slower than that around the edge of the ingot, thereby bringing about a different area in the radial direction of the ingot. Generally, the G value increases from the center of the ingot to the edge radially. Thus, when the pulling rate at the center is same as that around the edge, the VIG value at the center increases, causing an increase in the agglomerated vacancy point defect, while the other V/G value at the edge decreases, resulting an increase in the agglomerated interstitial point defect. The oxidation-induced stacking fault ring area exists at the boundary between these two areas, particularly in the direction somewhat inclined toward the vacancy area.

Accordingly, the method of producing an ingot according to the related art is unable to provide uniform cooling conditions such as temperature gradient and the like in the radial direction of the ingot due to weakness of the hot zone during the growth of the crystal. Specifically, heat at the center of the ingot is transferred to the edge of the ingot through conduction and then radiates therefrom, while the heat at the edge of the ingot is dissipated by radiation. Therefore, differences in the temperature gradient occur in the radial direction of the ingot. To reduce such a difference in temperature gradient, the temperature gradient at the ingot edge may be decreased or the temperature gradient at the center of the ingot may be increased.

Uniformity of cooling conditions in the radial direction of the ingot can be verified by a holding test, described in “Grown-in Microdefects, Residual Vacancies and Oxygen Precipitation Bands in Czochralski Silicon,” Journal of Crystal Growth 204, 462 (1999), by V. V Voronkov and R. Falster, which describes that specific oxygen precipitation patterns appear in an ingot crystal that was subjected to the holding test.

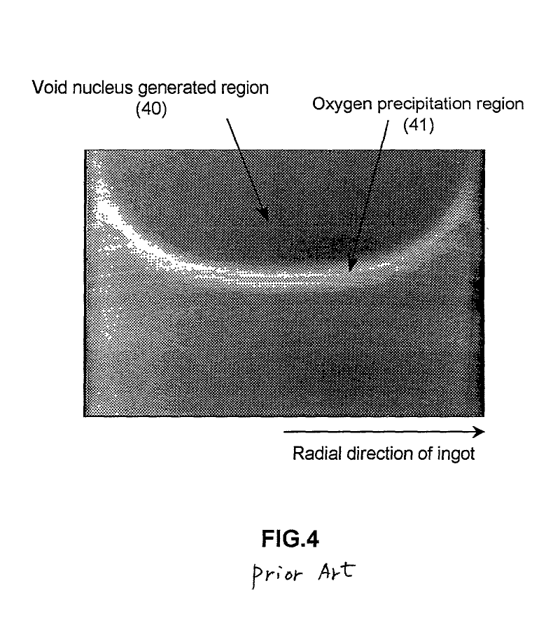

FIG. 4 shows an XRT image of a vertical cross-section of a single crystalline ingot subjected to the holding test at a hot zone according to the related art. Referring to FIG. 4, the bright region is an oxygen precipitation enhanced region 41, and a void nucleus generated region 40 exists above the oxygen precipitation enhanced region 41. Such region appears to the portion of the ingot on which temperature reaches about 1070° C. during the holding test.

In the hot zone according to the related art, the boundary between the oxygen precipitation region 41 and the void nucleus generated region 40 tends to be curved instead of being parallel, indicating indirectly that the point defect concentration in the crystal and cooling speed are not uniform radially.

### SUMMARY OF THE INVENTION

Accordingly, the present invention is directed to a single crystalline silicon ingot, a wafer and a method for their production in accordance with the Cz method that substantially obviates one or more of the problems due to limitations and disadvantages of the related art.

Additional features and advantages of the invention will be set forth in the description which follows and in part will be apparent from the description, or may be learned by practice of the invention. The objectives and other advantages of the invention will be realized and attained by the structure particularly pointed out in the written description as well as the appended drawings.

To achieve these and other advantages and in accordance with the purpose of the present invention, as embodied and broadly described, the present invention includes a single crystalline silicon ingot which has a central axis, a predetermined body having a diameter which is constant to the central axis, an edge and a radius extending from the central axis to the edge. The ingot includes a first area including the central axis wherein the body includes the central axis and wherein FPD and DSOD coexist centering around the central axis, a second area formed toward the edge of the ingot and adjacent to the first area wherein the second area has no FPD but DSOD, a third area formed toward the edge of the wafer and adjacent to the second area wherein an oxidation-induced stacking fault area exists, and a fourth area formed between the third area and the edge of the ingot wherein only an area free of agglomerated vacancy point defect exists or wherein the area free of agglomerated vacancy point defect and an area free of agglomerated interstitial point defect coexist in the fourth area. In a preferred embodiment, a total width of the second and third areas extends over 20-40% of the radius of the ingot, and a total length of the ingot including the second and third areas is equal to or greater than 20-40% of the body.

In another aspect, the present invention includes a wafer having a central axis and an edge which make a radius thereon, which comprises a first area including the central axis wherein FPD and DSOD coexist centering around the central axis, a second area formed toward the edge of the wafer and adjacent to the first area wherein the second area has no FPD but DSOD, a third area formed toward the edge of the wafer and adjacent to the second area wherein an oxidation-induced stacking fault area exists, and a fourth area formed between the third area and the edge of the wafer wherein only an area free of agglomerated vacancy point defect exists or wherein the area free of agglomerated vacancy point defect and an area free of agglomerated interstitial point defect coexist in the fourth area. In preferred embodiments, a total width of the second and third areas extends over 20-40% of the radius of the wafer.

In a further aspect, the present invention includes a method of producing a single crystalline silicon ingot by the Cz method, wherein the single crystalline silicon ingot has a central axis, a predetermined body with a diameter that is constant to the central axis, an edge and a radius extending from the central axis to the edge. The method includes a first step of adjusting an ingot growing condition and a cooling condition in a hot zone having a heat shield to shrink an oxidation-induced stacking fault ring abruptly in a radial direction of the ingot uniformly, a second step of determining a critical value of a pulling rate to maintain uniformity of the ingot growing condition and the cooling condition which are adjusted by the first step and to shrink the oxidation-induced stacking fault ring abruptly, and a third step of growing the ingot by maintaining the uniformity of the ingot growing condition and cooling condition as adjusted by the first step in the hot zone and by maintaining the critical value of the pulling rate as determined by the second step.

In a further aspect, the present invention includes a method of producing a single crystalline silicon ingot by the Cz method, wherein the single crystalline silicon ingot has a central axis, a predetermined body with a diameter that is constant to the central axis, an edge and a radius extending from the central axis to the edge. The method includes a first step of reducing an axial temperature gradient of the ingot edge by adjusting a melting gap; and increasing an axial temperature gradient of the ingot center by cooling down an upper part of the heat shield and an upper part of the ingot, wherein the first step adjusts an ingot growing condition and a cooling condition in a hot zone having a heat shield to shrink an oxidation-induced stacking fault ring abruptly in a radial direction of the ingot uniformly; a second step of inspecting uniformity of the ingot growing condition and cooling condition in the hot zone as adjusted by the first step through a holding test; a third step of determining a critical value of a pulling rate to shrink an oxidation-induced stacking fault ring abruptly by maintaining the uniformity of the ingot growing condition and cooling condition as adjusted by the second step; and a fourth step of growing the ingot by maintaining the uniformity of the ingot growing condition and cooling condition as adjusted by the second step in the hot zone and by maintaining the critical value of the pulling rate as determined by the third step.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention.

### IN THE DRAWINGS:

FIG. 1 is a picture of XRT(X-ray topography) showing a horizontal cross-sectional view of a single crystalline silicon ingot according to a related art;

FIG. 2 shows a vertical cross-sectional view of an ingot grown by varying a pulling rate, illustrating the formation of the respective defect areas, according to a related art;

FIG. 3 shows a horizontal cross-sectional view of an ingot corresponding to a region marked by I in FIG. 2, according to a related art;

FIG. 4 shows an XRT image of a vertical cross-section of a single crystalline ingot that was subjected to the holding test in a hot zone according to the related art;

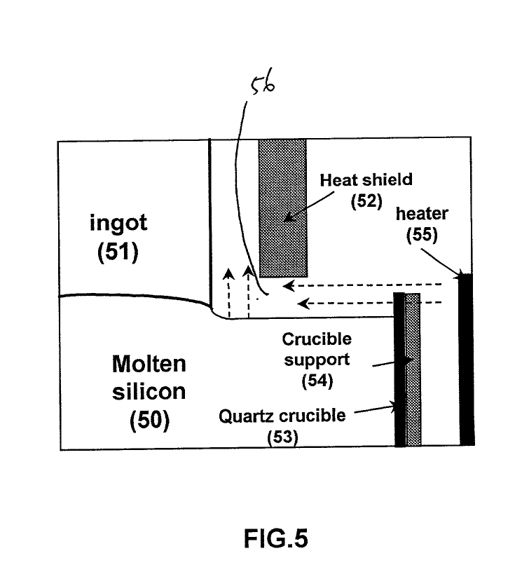

FIG. 5 schematically shows a hot zone near a single crystalline growing interface;

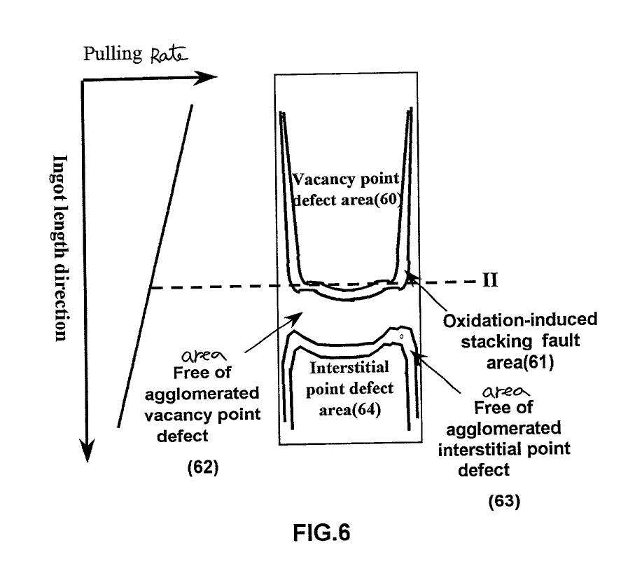

FIG. 6 shows a vertical cross-sectional view of an ingot, illustrating that an oxidation-induced stacking fault area shrinks in accordance with variation of the pulling rate when the uniformity of thermal history in the hot zone is increased according to an embodiment of the present invention;

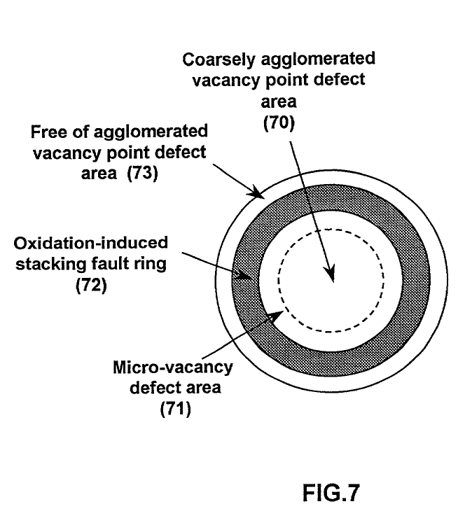

FIG. 7 shows a horizontal cross-sectional view of an ingot corresponding to a region indicated as II in FIG. 6;

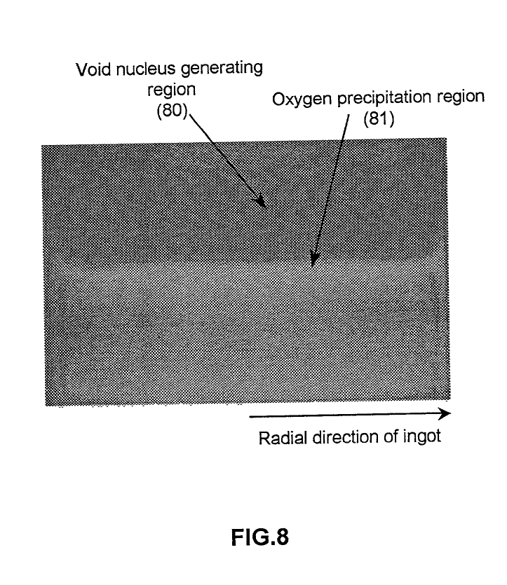

FIG. 8 shows an XRT vertical cross-sectional view of a single crystalline silicon ingot subjected to a holding test in a hot zone where the uniformity of thermal history is uniform according to an embodiment of the present invention;

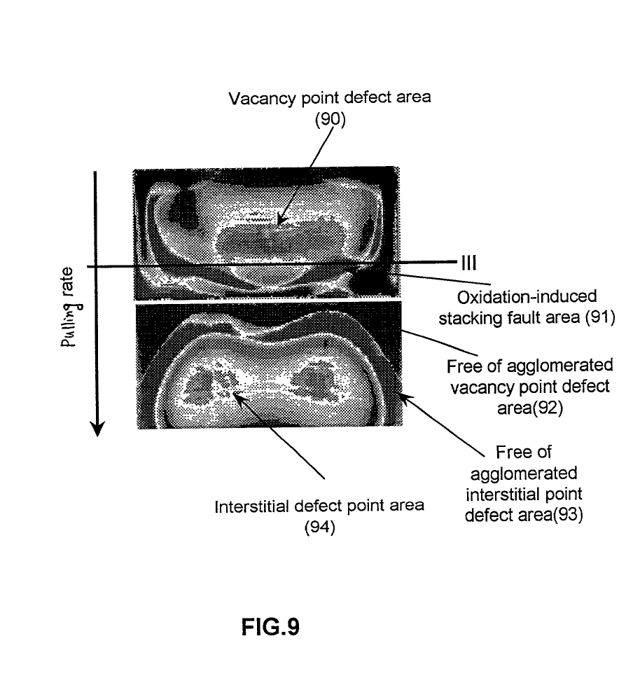

FIG. 9 shows a scan of the minority carrier lifetime of a vertical cross-section of the single crystalline silicon ingot of FIG. 6;

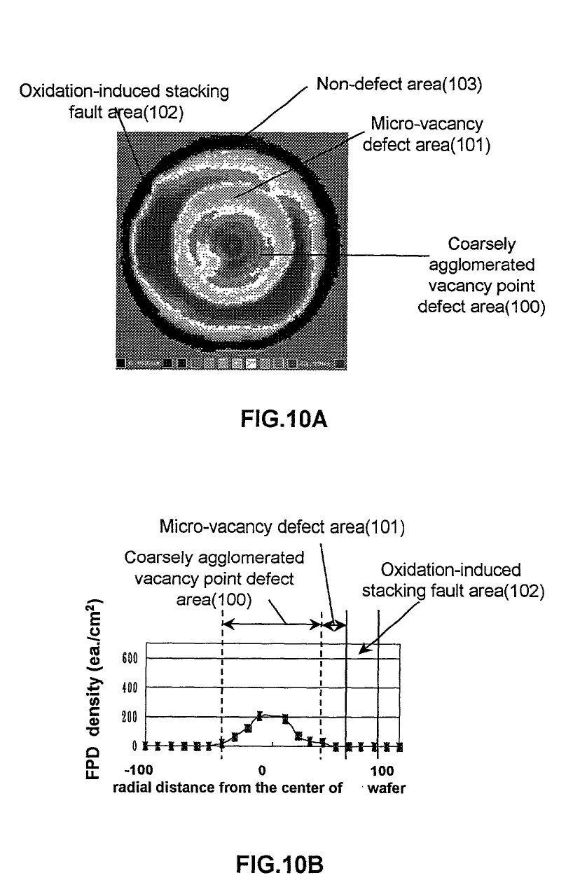

FIG. 10A shows a scan of the minority carrier lifetime of the horizontal cross-section indicated as III in FIG. 9;

FIG. 10B shows a FPD distribution corresponding radially to FIG. 10A;

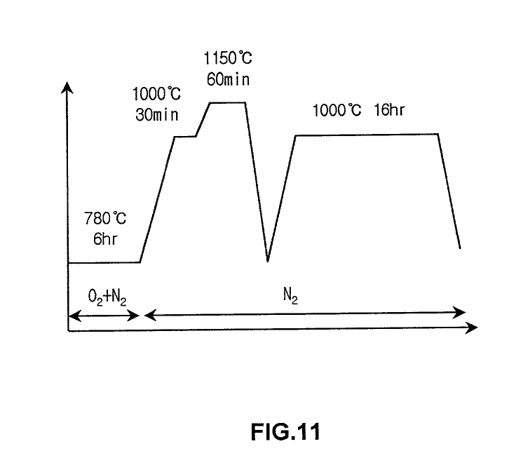

FIG. 11 shows a heat treatment cycle for a 256M DRAM device schematically;

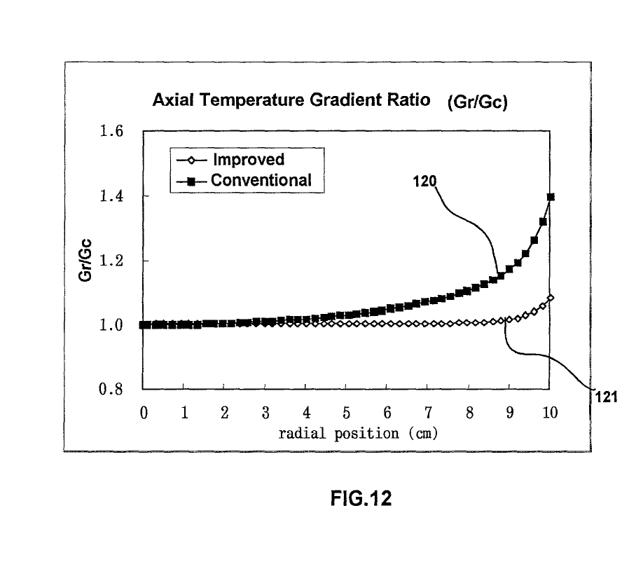

FIG. 12 shows graphs of axial temperature gradient ratios of the present invention and the related art from the center to the edge of an ingot;

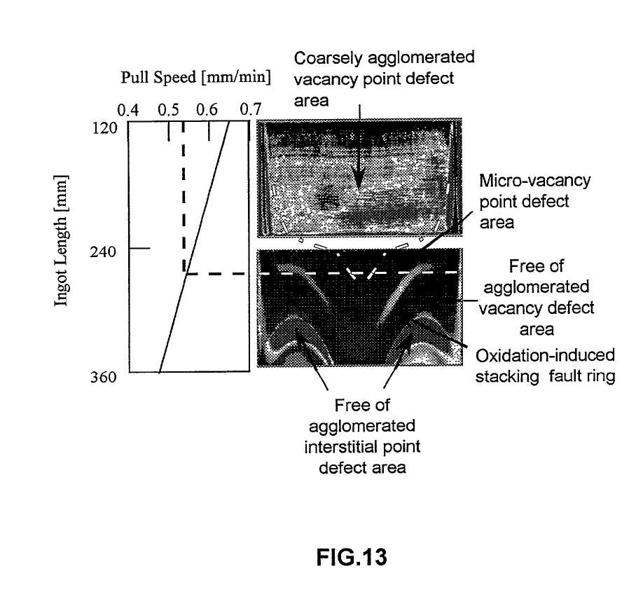

FIG. 13 shows a vertical cross-section of a single crystalline silicon ingot being matched with a pulling rate according to an embodiment of the present invention; and

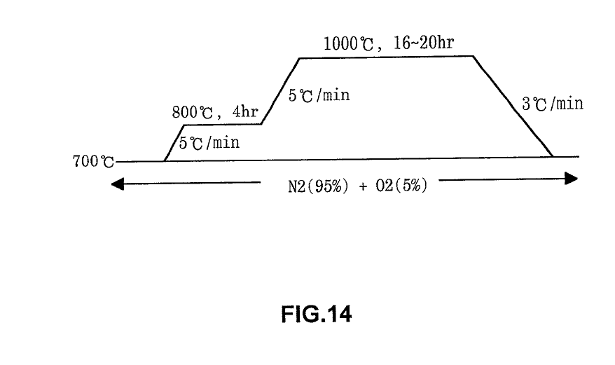

FIG. 14 shows a heat treatment cycle for inspecting oxidation-induced stacking fault.

### DETAILED DESCRIPTION OF THE PREFERRED EMBODIMENTS

Reference will now be made in detail to the preferred embodiments of the present invention, examples of which are illustrated in the accompanying drawings.

The terminology's and abbreviations used in the specification are as follows.

Micro-vacancy defect area: A semiconductor wafer needs to be free of significant defect to secure the processes for forming various electronic circuits thereon as well as operation of the circuits as designed. To detect large defects causing malfunctions of the electronic circuits on the semiconductor wafer itself, there are various ways named after the finders such as COP, FPD, LSTD, OiSF, DSOD and the like, defined below. Micro-vacancy defect area means an area where DSOD may be found but no operational malfunction occurs on electronic circuits over 64M DRAM, and where COP, FPD, and LSTD are not found. Namely, a wafer is suitable for producing IC over 64 M DRAM provided that there is no COP, FPD and LSTD, but DSOD may occur.

MCLT: Minority Carrier Life Time

COP: Crystal Originated Particle

FPD: Flow Pattern Defect

LSTD: Light Scattering Topography Defect

OiSF: Oxidation-induced Stacking Fault Ring

DSOD: Direct Surface Oxide Defect

BMD: Bulk Micro-Defect

DZ: Denuded Zone

XRT: X-Ray Topography

The present invention is based on the fact that chip yield is maintained, even if an oxygen precipitation defect region having a nucleus of potential oxidation induced stacking fault (“OiSF”) exists in a single crystalline silicon ingot, since the oxygen precipitation defect region develops into an oxidation-induced stacking fault area in the real semiconductor producing process. The present invention enhances the oxidation-induced stacking fault area in the final wafer by minimizing thermal history difference in the radial direction of an ingot. Thus, the agglomerated vacancy point defect area existing inside the oxidation-induced stacking fault area is reduced. As a result, density or size of the agglomerated vacancy point defect area, which may include COP, FPD and the like, is also reduced since defect distribution in the radial direction of a wafer becomes uniform.

FIG. 2 shows a vertical cross-sectional view of an ingot grown by varying a pulling rate, illustrating the formation of the respective defect areas according to the related art. FIG. 6 shows a vertical cross-sectional view of an ingot, illustrating that an oxidation-induced stacking fault area 61 shrinks in accordance with variation of the pulling rate when the uniformity of thermal history in the hot zone is increased according to an embodiment of the present invention.

Referring to FIG. 2 and FIG. 6, contraction of the oxidation-induced stacking fault area 61 occurs as the pulling rate is reduced, with the slope of the contraction becoming steep when the uniformity of the radial growth and the cooling condition of the ingot is increased. The present invention introduces the following method to make the growth and cooling conditions of the crystal uniform radially.

First, the axial temperature gradient of the ingot edge is reduced by controlling the heat radiated to the ingot edge from a heater by controlling a melting gap. Second, the axial temperature gradient of the center of the ingot is increased by cooling down the upper parts of the ingot and the heat shield.

FIG. 5 schematically shows a hot zone near a single crystalline growing interface. Referring to FIG. 5, the difference in cooling speeds at the respective radial locations of the ingot is lessened by reducing the cooling speed of the ingot edge using a heat shield 52 and radiating heat from a heater 55 and a melt-down silicon 50. In this case, the heat shield 52 is made of a thermally-insulating substance so as not to transfer heat from the melt-down silicon 50 to the upper part of the ingot 51. In addition, the cooling speed of the ingot edge near the crystal growing interface is decreased by preventing the heat from being easily leaked through the melting gap, that is, a space 56 between a bottom of the heat shield 52 and a surface of the melt-down silicon 50. Moreover, the cooling condition is controlled by varying a size of the ingot 51 and the radiating heat from the heater 55 by adjusting the height of the melting gap 56.

FIG. 7 shows a horizontal cross-sectional view of an ingot corresponding to a region indicated as II in FIG. 6.

Compared to the related art in FIG. 3, the present invention shows that an oxidation-induced stacking fault ring 72 is widely distributed over a cross-section of an ingot and that the size of a vacancy defect area located at the center of the ingot is reduced. The vacancy defect area includes a micro-vacancy defect area 71 and a coarsely agglomerated vacancy point defect area 70. In this case, the micro-vacancy defect area 71 does not have FPD but may have DSOD, while the coarsely agglomerated vacancy point defect area 70 means that FPD and DSOD co-exist therein.

DSOD means that the size of any defect is significantly smaller than that of FPD near the wafer surface. As the integration of a chip increases, the design rule of a device decreases abruptly. It is known that a wafer to be used for a VLSI device over 64 or 128 MB cannot tolerate FPD but may have DSOD. Thus, the micro-vacancy defect area where only DSOD exists is acceptable for the wafer be used to fabricate IC over 64 MB.

The uniformity of a cooling condition in the radial direction of an ingot can be verified by a holding test. FIG. 8 shows an XRT vertical cross-sectional view of a single crystalline silicon ingot that was subjected to a holding test in a hot zone where the thermal history is uniform according to an embodiment of the present invention. Compared to the vertical cross-sectional view in FIG. 4, FIG. 8 shows that the boundary between the oxygen precipitation region 81 and the void nucleus generating region 80 is formed in parallel to the radial direction of the ingot, thereby indicating that the point defect concentration and cooling speed in the crystal are radially uniform.

A heat shield, which is designed to provide a uniform cooling condition inside the ingot near the growing boundary radially, cuts off heat from the melt-down silicon and allows the crystal to easily cool down, while also slowing down the cooling of temperature at the crystal surface between the heat shield and the melt-down silicon, thereby eventually reducing the difference of cooling speeds between the surface and inside of the crystal. The radial uniformity of cooling speed is improved by controlling the melting gap, and the result of the holding test which verifies the uniformity is shown in FIG. 8.

The single crystalline silicon ingot is grown by minimizing the radial difference of thermal history and by reducing the pulling rate. In this case, oxygen concentration is set to 8 to 12 ppma by controlling the revolution speed of a quartz crucible 53 having a crucible support 54, and the flow of ambient gas.

FIG. 9 shows a scan of the Minority Carrier Life Time (“MCLT”) of a vertical cross-section of the single crystalline silicon ingot of FIG. 6. Referring to FIG. 9, a vacancy defect area 90 prevails as the pulling rate increases, while an interstitial defect area 94 appears as the pulling rate decreases. In this figure a pulling rate where an oxidation-induced stacking fault area 91 between the vacancy defect area 90 and the interstitial defect area 94 appears can be determined. In the embodiment of the present invention, the actual pulling rate generating the oxidation-induced stacking fault area 91 is equal to or faster than 0.5 mm/min., which will be explained in detail later.

FIG. 10A shows a scan of the MCLT of the horizontal cross-section designated by III in FIG. 9 where the oxidation-induced stacking fault area 91 appears. Referring to FIG. 10A, an oxidation-induced stacking fault area 102 inside of which a micro-vacancy defect area 101 and a coarsely agglomerated vacancy point defect area 100 exist is distributed near an edge of the ingot. A non-defect area 103, where point defects of non-condensed state exist, is located outside the oxidation-induced stacking fault area.

FIG. 10B shows a FPD distribution corresponding radially to FIG. 10A. Referring to FIG. 10B, a coarsely agglomerated vacancy point defect area 100 where FPD is condensed is located at the center of the wafer. A micro-vacancy defect area 101, where DSOD appears without FPD, is adjacent to the coarsely agglomerated vacancy point defect area 100. An oxidation-induced stacking fault area 102 exists near the micro-vacancy defect area 101 on the wafer. It is desirable to have the FPD density set under 250 ea./cm². A device yield can be improved by reducing the coarsely agglomerated vacancy point defect area 100 when a defect causing trouble in the device production process only exists in the coarsely agglomerated vacancy point defect area 100.

FIG. 11 schematically shows heat treatment cycle for a 256M DRAM device. With the heat treatment cycle of FIG. 11, no defect is detected in the oxidation-induced stacking fault on a wafer fabricated from an ingot in FIG. 10A. Therefore, it is possible to reduce or eventually eliminate the coarsely agglomerated vacancy point defect area by growing the ingot to enhance the oxidation-induced stacking fault area according to the embodiment of the present invention.

FIG. 12 shows graphs of axial temperature gradient ratios of the present invention and the related art from the center to the edge of an ingot. The ingot in accordance with an embodiment of the present invention is grown at a hot zone where the difference of thermal history is minimized in the radial direction of the ingot, wherein Gr is an axial temperature gradient at an arbitrary point on an ingot radius and Gc is an axial temperature gradient from the ingot center.

According to FIG. 12, a radial curve 121 of the axial temperature gradient of the present invention is slower than a curve 120 of the related art, thereby indicating that the difference of the axial temperature gradient of the present invention is smaller in the radial direction of the ingot than that of the related art.

TABLE 1

| Items | Conventional | Improved |
|---|---|---|
| ΔG (K/cm) | 16.49 | 2.87 |
| G_{1,c} (K/cm) | 13.29 | 32.31 |
| G_{1,e} (K/cm) | 11.25 | 43.55 |
| G_{2,c} (K/cm) | 10.94 | 23.81 |
| G_{2,e} (K/cm) | 9.94 | 26.14 |

Table 1 shows axial temperature gradients and differences of temperature gradient of ingots according to the related art and the present invention, wherein ΔG is a difference between axial temperature gradients of an ingot edge and an ingot center, adjacent to an interface of the melt-down silicon. G1,c is an average value of an axial temperature gradient of the ingot center where COP is generated between 1120° C.˜1070° C., G1,e is an average value of an axial temperature gradient of the ingot edge where COP is generated between 1120° C.˜1070° C., G2,c is an average value of an axial temperature gradient of the ingot center where OiSF nucleus is generated between 1070° C.˜800° C., and G2,e is an average value of an axial temperature gradient of the ingot edge where OiSF nucleus is generated between 1070° C.˜800° C.

The difference ΔG in axial temperature gradient between an ingot edge and an ingot center, adjacent to an interface of the melt-down silicon, is defined by the formula: ΔG(K/cm)=Ge−Gc, where Ge and Gc are axial temperature gradients of the ingot edge and the ingot center, respectively.

Referring to Table 1, ΔG of the related art is 16.49 K/cm, while ΔG of the present invention is 2.87K/cm, clearly reducing the difference of temperature gradient. In the embodiment of the present invention, ΔG is maintained under 3K/cm.

Average values, which are greater than those of the related art, of axial temperature gradient of the ingot center and the ingot edge between an interval 1120° C. to 1070° C., where COP is mainly generated, are 32.31 K/cm and 43.55K/cm, respectively. Average values, which are much greater than those of the related art, of axial temperature gradient of the ingot center and the ingot edge between an interval 1070 to 800° C., where OiSF nucleus is mainly generated, are 23.81 K/cm and 26.14K/cm, respectively. Therefore, the temperature interval during which the defects are generated passes so quickly that the defects have less chance to be generated.

FIG. 13 shows a vertical cross-section of a single crystalline silicon ingot being matched with a pulling rate according to an embodiment of the present invention, wherein an image is attained by carrying out thermal treatment on the cross-section of the ingot grown by reducing the pulling rate from 0.65 mm/min. to 0.48 mm/min. in accordance with the cycle in FIG. 14, and then by scanning the cross-section with MCLT. FIG. 14 shows a heat treatment cycle for inspecting oxidation-induced stacking fault area.

Referring to FIG. 13, it is desirable to keep the pulling rate over 0.5 mm/min. for this embodiment of the present invention.

Accordingly, an oxidation-induced stacking fault area having a micro-vacancy defect area of low density is distributed widely from the ingot edge to the ingot center in a single crystalline silicon ingot and a wafer fabricated by the present invention. As the micro-vacancy defect area has no FPD but may have DSOD, a coarsely agglomerated vacancy point defect area in which FPD and DSOD cohabit is greatly reduced or even eliminated. Therefore, the present invention enables improvement in the product quality as well as device yield.

It will be apparent to those skilled in the art that various modifications and variations can be made in a single crystalline silicon ingot, a wafer and a method of producing a single crystalline silicon ingot of the present invention without departing from the spirit or scope of the invention. Thus, it is intended that the present invention cover the modifications and variations of this invention provided they come within the scope of the appended claims and their equivalents.

What is claimed is:

1. A wafer having a central axis and an edge which make a radius thereon, the wafer comprising:
a first area including the central axis wherein FPD and DSOD coexist centering around the central axis;
a second area formed toward the edge of the wafer and adjacent to the first area, the second area having no FPD;
a third area formed toward the edge of the wafer and adjacent to the second area, wherein an oxidation-induced stacking fault area exists; and
a fourth area formed between the third area and the edge of the wafer wherein an area free of agglomerated vacancy point defect exists.

2. The wafer according to claim 1, wherein the area free of agglomerated vacancy point defect and an area free of agglomerated interstitial point defect coexist in the fourth area.

3. The wafer according to claim 1, wherein the second area has vacancy defect smaller than that of the first area.

4. The wafer according to claim 1, wherein a total width of the second and third areas extends over 20% of the radius of the wafer.

5. The wafer according to claim 1, wherein a total width of the second and third areas extends over 30% of the radius of the wafer.

6. The wafer according to claim 1, wherein a total width of the second and third areas extends over 40% of the radius of the wafer.

7. The wafer according to claim 1, wherein a FPD density in a FPD region is under 250 ea./cm².

8. The wafer according to claim 1, wherein initial oxygen concentration is approximately 12 ppma.

9. The wafer according to claim 1, wherein initial oxygen concentration is approximately 8 ppma.

10. A single crystalline silicon ingot having a central axis, a predetermined body with a diameter that is constant to the central axis, an edge and a radius extending from the central axis to the edge, the single crystalline ingot comprising:
a first area including the central axis wherein the body includes the central axis and wherein FPD and DSOD coexist centering around the central axis;
a second area formed toward the edge of the ingot and adjacent to the first area, wherein the second area having no FPD;
a third area formed toward the edge of the wafer and adjacent to the second area, wherein an oxidation-induced stacking fault area exists; and
a fourth area formed between the third area and the edge of the ingot wherein an area free of agglomerated vacancy point defect exists.

11. The ingot according to claim 10, wherein the area free of agglomerated vacancy point defect and an area free of agglomerated interstitial point defect coexist in the fourth area.

12. The single crystalline silicon ingot according to claim 10, wherein the second area has vacancy defect smaller than that of the first area.

13. The single crystalline silicon ingot according to claim 10, wherein a total width of the second and third areas extends over 20% of the radius of the ingot.

14. The single crystalline silicon ingot according to claim 10, wherein a total width of the second and third areas extends over 30% of the radius of the ingot.

15. The single crystalline silicon ingot according to claim 10, wherein a total width of the second and third areas extends over 40% of the radius of the ingot.

16. The single crystalline silicon ingot according to claim 1 0, wherein ingot length including the second and third areas is equal to or greater than 20% of the body.

17. The single crystalline silicon ingot according to claim 10, wherein ingot length including the second and third areas is equal to or greater than 30% of the body.

18. The single crystalline silicon ingot according to claim 10, wherein ingot length including the second and third areas is equal to or greater than 40% of the body.

19. The single crystalline silicon ingot according to claim 10, wherein a FPD density in a FPD region is under 250 ea./cm².

20. The single crystalline ingot according to claim 10, wherein initial oxygen concentration is approximately 12 ppma.

21. The single crystalline ingot according to claim 10, wherein initial oxygen concentration is approximately 8 ppma.

22. A method of producing a single crystalline silicon ingot by Czochralski method, the single crystalline silicon ingot having a central axis, a center adjacent to the central axis, a predetermined body in which a diameter is constant to the central axis, an edge and a radius extending from the central axis to the edge, the method comprising the steps of:
adjusting an ingot growing condition and a cooling condition in a hot zone having a heat shield to shrink an oxidation-induced stacking fault ring abruptly and uniformly in a radial direction of the ingot;
determining a critical value of a pulling rate necessary to maintain uniformity of the ingot growing condition and the cooling condition and to shrink the oxidation-induced stacking fault ring abruptly as set in the adjusting step; and
growing the ingot by maintaining the uniformity of the ingot growing condition and cooling condition in the hot zone, as set in the adjusting step, and by maintaining the critical value of the pulling rate determined by the determining step.

23. The method according to claim 22, wherein the adjusting step is verified by a holding test.

24. The method according to claim 22, wherein the adjusting step reduces an axial temperature gradient of the ingot edge by adjusting a melting gap.

25. The method according to claim 22, wherein the adjusting step increases an axial temperature gradient of the ingot center by cooling down an upper part of the heat shield and an upper part of the ingot.

26. The method according to claim 22, wherein the critical value of the pulling rate is equal to or faster than 0.5 mm/min.

27. The method according to claim 22, wherein a difference of axial temperature gradients between the ingot edge and the ingot center is equal to or less than 3K/cm.

28. The method according to claim 22, wherein the ingot grown by the growing step comprises:
a first area including the central axis wherein FPD and DSOD coexist centering around the central axis;
a second area formed toward the edge of the wafer and adjacent to the first area, the second area having no FPD;
a third area formed toward the edge of the wafer and adjacent to the second area, wherein an oxidation-induced stacking fault area exists; and
a fourth area formed between the third area and the edge of the wafer wherein an area free of agglomerated vacancy point defect exists.

29. The method according to claim 28, wherein the area free of agglomerated vacancy point defect and an area free of agglomerated interstitial point defect coexist in the fourth area.

30. The method according to claim 28, wherein the third area occupies over 20% of the radius of the ingot.

31. The method according to claim 28, wherein the third area occupies over 30% of the radius of the ingot.

32. The method according to claim 28, wherein the third area occupies over 40% of the radius of the ingot.

33. The method according to claim 28, wherein an ingot length of a portion including the second and third areas is equal to or longer than 20% of the body.

34. The method according to claim 28, wherein an ingot length of a portion including the second and third areas is equal to or longer than 30% of the body.

35. The method according to claim 28, wherein an ingot length of a portion including the second and third areas is equal to or longer than 40% of the body.

36. The method according to claim 28, wherein a FPD density in a FPD region is under 250 ea./cm².

37. The method according to claim 28, wherein initial oxygen concentration is approximately 12 ppma.

38. The method according to claim 28, wherein initial oxygen concentration is approximately 8 ppma.

39. A method of producing a single crystalline silicon ingot by Czochralski method, the single crystalline silicon ingot having a central axis, a center adjacent to the central axis, a predetermined body with a diameter substantially constant to the central axis, an edge and a radius extending from the central axis to the edge, the method comprising the steps of:
adjusting an ingot growing condition and a cooling condition in a hot zone having a heat shield to shrink an oxidation-induced stacking fault ring abruptly and uniformly in a radial direction of the ingot;
inspecting uniformity of the ingot growing condition and cooling condition in the hot zone as adjusted by the adjusting step through a holding test;
determining a critical value of a pulling rate necessary to shrink the oxidation-induced stacking fault ring abruptly while maintaining the uniformity of the ingot growing condition and cooling condition as adjusted by the adjusting step; and
growing the ingot by maintaining the uniformity of the ingot growing condition and cooling condition as adjusted by the adjusting step in the hot zone and by maintaining the critical value of the pulling rate determined by the determining step.

40. The method according to claim 39, said adjusting step comprising the steps of:
reducing an axial temperature gradient of the ingot edge by adjusting a melting gap; and
increasing an axial temperature gradient of the ingot center by cooling down an upper part of the heat shield and an upper part of the ingot.

41. The method according to claim 40, wherein the critical value of the pulling rate is equal to or faster than 0.5 mm/min.

42. The method according to claim 40, wherein a difference of axial temperature gradients between the ingot edge and the ingot center is equal to or smaller than 3K/cm.

43. The method according to claim 40, wherein the ingot grown by the growing step comprises:
a first area including the central axis wherein FPD and DSOD coexist centering around the central axis;
a second area formed toward the edge of the wafer and adjacent to the first area, the second area having no FPD;
a third area formed toward the edge of the wafer and adjacent to the second area wherein an oxidation-induced stacking fault area exists; and
a fourth area formed between the third area and the edge of the wafer wherein an area free of agglomerated vacancy point defect exists.

44. The method according to claim 43, wherein the area free of agglomerated vacancy point defect and an area free of agglomerated interstitial point defect coexist in the fourth area.

45. The method according to claim 43, wherein the third area occupies over 20% of the radius of the ingot.

46. The method according to claim 43, wherein the third area occupies over 30% of the radius of the ingot.

47. The method according to claim 43, wherein the third area occupies over 40% of the radius of the ingot.

48. The method according to claim 43, wherein an ingot length of a portion including the second and third areas is equal to or longer than 40% of the body.

49. The method according to claim 43, wherein an ingot length of a portion including the second and third areas is equal to or longer than 30% of the body.

50. The method according to claim 43, wherein an ingot length of a portion including the second and third areas is equal to or longer than 40% of the body.

51. The method according to claim 43, wherein a FPD density in a FPD region is under 250 ea./cm².

52. The method according to claim 43, wherein initial oxygen concentration is approximately 12 ppma.

53. The method according to claim 43, wherein initial oxygen concentration is approximately 8 ppma.
